(19) United States
(12) Patent Application Publication
(10) Pub. No.: US 2025/0349594 A1
(43) Pub. Date: Nov. 13, 2025

(54) CONTROLLABLE OXIDE RECESS PROFILE THROUGH VARIOUS WET OXIDATION PROCESSES

(71) Applicant: Taiwan Semiconductor Manufacturing Co., Ltd., Hsinchu (TW)

(72) Inventors: Hui-Jou Su, Hsinchu (TW); Keng Fang Hsu, Hsinchu (TW); Tzu-Wei Kao, Baoshan Township (TW); Tsai-Jhen Kuo, Kaohsiung City (TW); Chun-Hsiang Fan, Hsinchu (TW); Tsu-Hui Su, Taipei City (TW)

(21) Appl. No.: 18/809,034

(22) Filed: Aug. 19, 2024

Related U.S. Application Data
(60) Provisional application No. 63/645,498, filed on May 10, 2024.

(51) Int. Cl. H01L 21/762; H01L 21/02; H01L 29/66

(52) U.S. Cl. CPC H01L 21/76202; H01L 21/0228; H01L 21/76224; H10D 30/014; H10D 64/017; H10D 64/018

(57) ABSTRACT

A method includes forming a multilayer stack over a semiconductor region, wherein the multilayer stack comprises a plurality of sacrificial layers and a plurality of semiconductor nanostructures located alternatingly. The method further includes removing the plurality of sacrificial layers, forming a plurality of disposable interposers between the plurality of semiconductor nanostructures, performing an oxidation process on the plurality of disposable interposers, laterally recessing the plurality of disposable interposers to form lateral recesses between the plurality of semiconductor nanostructures, forming inner spacers in the lateral recesses, removing the plurality of disposable interposers, and forming a replacement gate in spaces between the plurality of semiconductor nanostructures.

### PRIORITY CLAIM AND CROSS-REFERENCE

This application claims the benefit of the following provisionally filed U.S. patent application: Application No. 63/645,498, filed on May 10, 2024, and entitled “CONTROLLABLE OXIDE RECESS PROFILE BY VARIOUS WET OXIDATION,” which application is hereby incorporated herein by reference.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (for example, transistors, diodes, resistors, capacitors, etc.) through continual reduction in minimum feature size, which allows more components to be integrated into a given area. As the minimum feature sizes are reduced, however, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-5A, 5B, 6A, 6B, 7A, 7B and 8 through 20 illustrate the views of intermediate stages in the formation of nanostructure transistors in accordance with some embodiments.

FIG. 21 illustrates the structure change of a dielectric layer in an oxidation process in accordance with some embodiments.

FIG. 22 illustrates a process flow for forming nanostructure transistors in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Gate-All-Around (GAA) transistors (also referred to as nanostructure transistors) and the method of forming the same are provided. In accordance with some embodiments of the present disclosure, semiconductor nanostructures, which form the channel regions of the GAA transistors, are formed. The sacrificial layers between the semiconductor nanostructures are removed, and are replaced with disposable interposers. The formation of the disposable interposers may include depositing a first dielectric layer and a second dielectric layer. An oxidation process is then performed to oxidize the disposable interposers. Through the oxidation process, the quality of the disposable interposers may be improved. Furthermore, by performing the oxidation processes through different process conditions, the resulting disposable interposers may have different profiles, which in turn affect the performance of the resulting transistors.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

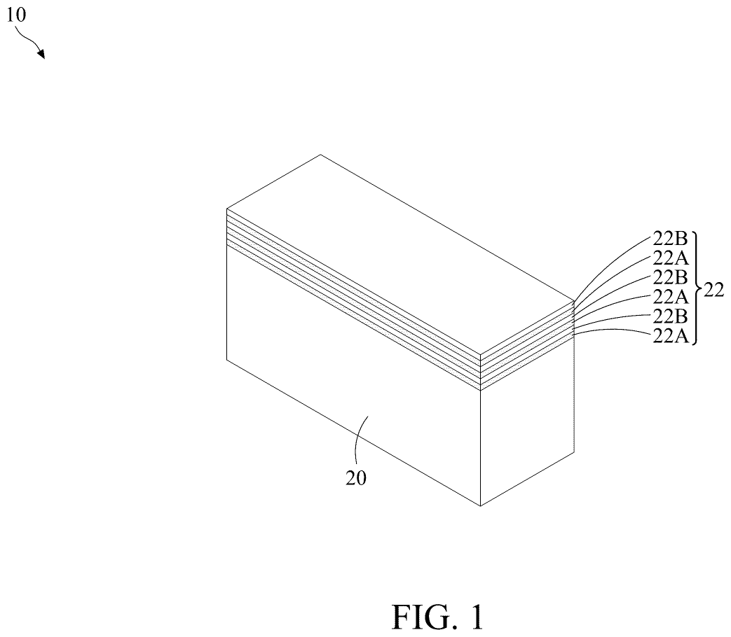

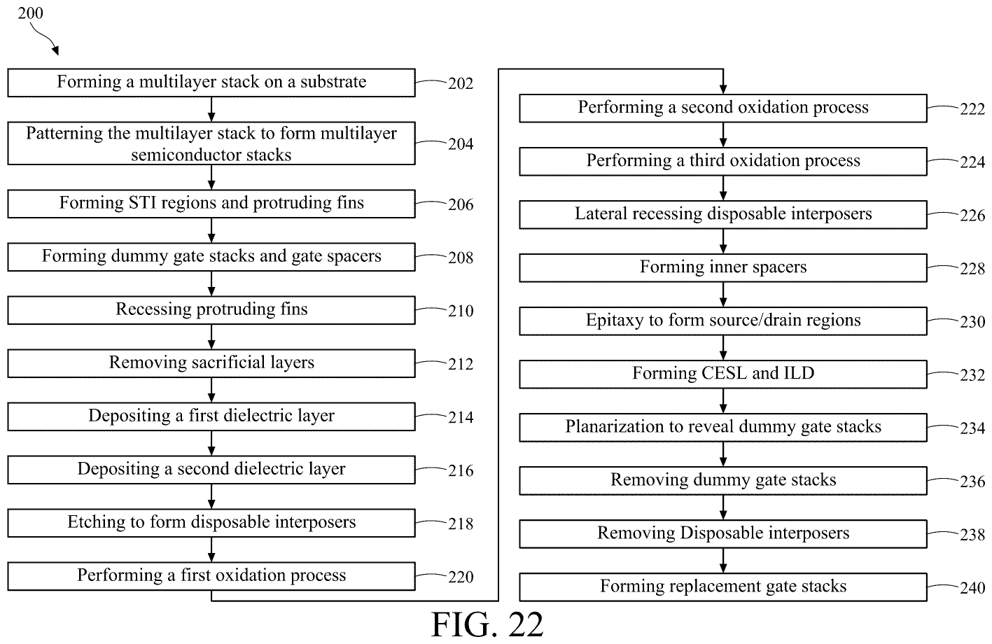

FIGS. 1 through 20 illustrate the cross-sectional views of intermediate stages in the formation of GAA transistors in accordance with some embodiments of the present disclosure. The corresponding processes are also reflected schematically in the process flow shown in FIG. 22.

Referring to FIG. 1, a perspective view of wafer 10 is shown. Wafer 10 includes a multilayer structure comprising multilayer stack 22 on substrate 20. In accordance with some embodiments, substrate 20 is a semiconductor substrate, which may be a silicon substrate, a silicon germanium (SiGe) substrate, or the like, while other substrates and/or structures, such as semiconductor-on-insulator (SOI), strained SOI, silicon germanium on insulator, or the like, could be used. Substrate 20 may be doped as a p-type semiconductor, although in other embodiments, it may be doped as an n-type semiconductor.

In accordance with some embodiments, multilayer stack 22 is formed through a series of deposition processes for depositing alternating materials. The respective process is illustrated as process 202 in the process flow 200 shown in FIG. 22. In accordance with some embodiments, multilayer stack 22 comprises first layers 22A formed of a first semiconductor material and second layers 22B formed of a second semiconductor material different from the first semiconductor material.

In accordance with some embodiments, the first layers 22A are formed of or comprise a first semiconductor material such as SiGe, Ge, Si, GaAs, InSb, GaSb, InAlAs, InGaAs, GaSbP, GaAsSb, or the like. In accordance with some embodiments, the deposition of the first layers 22A (for example, SiGe) is through epitaxial growth, and the corresponding deposition method may be Vapor-Phase Epitaxy (VPE), Molecular Beam Epitaxy (MBE), Chemical Vapor deposition (CVD), Low Pressure CVD (LPCVD), Atomic Layer Deposition (ALD), Ultra High Vacuum CVD (UHVCVD), Reduced Pressure CVD (RPCVD), or the like.

The second layers 22B are formed of or comprise a second semiconductor material such as Si, SiGe, Ge, GaAs, InSb, GaSb, InAlAs, InGaAs, GaSbP, GaAsSb, combinations of these, or the like, with the second semiconductor material being different from the first semiconductor material of the first layers 22A. For example, in accordance with some embodiments in which the first layers 22A comprise silicon germanium, the second layers 22B may be formed of silicon, or vice versa. It is appreciated that any suitable combination of materials may be utilized for first layers 22A and the second layers 22B.

In accordance with some embodiments, the second layers 22B are epitaxially grown on the first layer 22A using a deposition technique similar to that is used to form the first layers 22A. The deposition process for forming alternating first layers 22A and second layers 22B is repeated to form the remaining layers in multilayer stack 22, until a desired topmost layer of multilayer stack 22 has been formed.

In accordance with some embodiments, first layers 22A have thicknesses the same as or similar to each other, and second layers 22B have thicknesses the same as or similar to each other. First layers 22A may also have the same thicknesses as, or different thicknesses from, that of second layers 22B. In accordance with some embodiments, first layers 22A will be removed in the subsequent processes, and are alternatively referred to as sacrificial layers 22A throughout the description.

In accordance with some embodiments, there may be some pad oxide layer(s) and hard mask layer(s) (not shown) formed over multilayer stack 22. These layers are patterned, and are used for the subsequent patterning of multilayer stack 22.

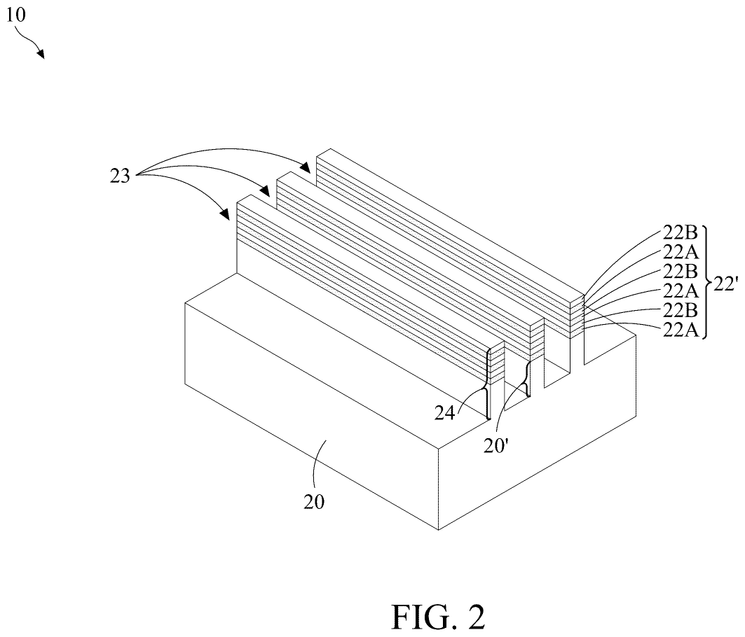

Referring to FIG. 2, multilayer stack 22 and a portion of the underlying substrate 20 are patterned in an etching process(es), so that trenches 23 are formed. The respective process is illustrated as process 204 in the process flow 200 shown in FIG. 22. Trenches 23 extend into substrate 20. The remaining portions of multilayer stacks are referred to as multilayer stacks 22′ hereinafter. Underlying multilayer stacks 22′, some portions of substrate 20 are left, and are referred to as substrate strips 20′ hereinafter. Multilayer stacks 22′ include semiconductor layers 22A and 22B. Semiconductor layers 22A are alternatively referred to as sacrificial layers, and Semiconductor layers 22B are alternatively referred to as nanostructures hereinafter. The portions of multilayer stacks 22′ and the underlying substrate strips 20′ are collectively referred to as semiconductor strips 24.

In above-illustrated embodiments, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

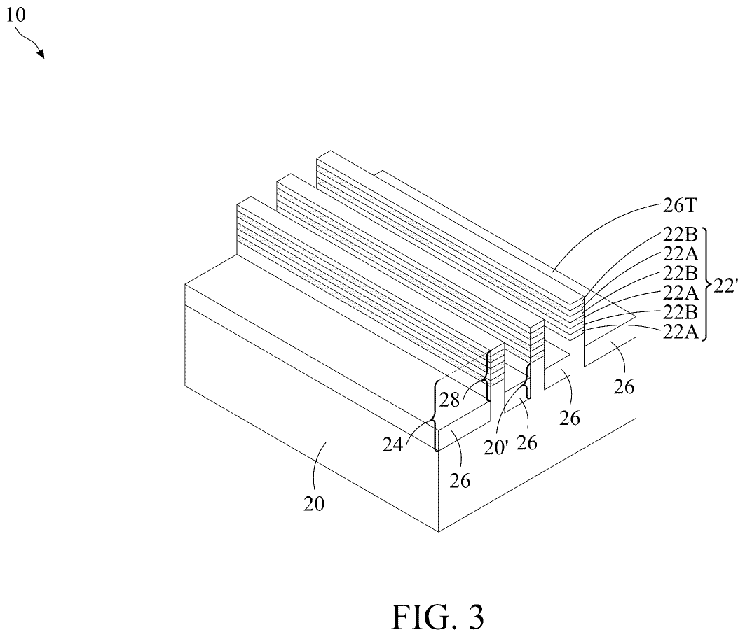

FIG. 3 illustrates the formation of isolation regions 26, which are also referred to as Shallow Trench Isolation (STI) regions throughout the description. The respective process is illustrated as process 206 in the process flow 200 shown in FIG. 22. STI regions 26 may include a liner oxide (not shown), which may be a thermal oxide formed through the thermal oxidation of a surface layer of substrate 20, or may be deposited. The liner oxide may also be a deposited silicon oxide layer formed using, for example, ALD, High-Density Plasma Chemical Vapor Deposition (HDPCVD), CVD, or the like. STI regions 26 may also include a dielectric material over the liner oxide, wherein the dielectric material may be formed using Flowable Chemical Vapor Deposition (FCVD), spin-on coating, HDPCVD, or the like. A planarization process such as a Chemical Mechanical Polish (CMP) process or a mechanical grinding process may then be performed to level the top surface of the dielectric material, and the remaining portions of the dielectric material are STI regions 26.

STI regions 26 are then recessed, so that the top portions of semiconductor strips 24 protrude higher than the top surfaces 26T of the remaining portions of STI regions 26 to form protruding fins 28. Protruding fins 28 include multilayer stacks 22′ and the top portions of substrate strips 20′. The recessing of STI regions 26 may be performed through a dry etching process, wherein NF₃ and NH₃, for example, are used as the etching gases. During the etching process, plasma may be generated. Argon may also be included. In accordance with alternative embodiments of the present disclosure, the recessing of STI regions 26 is performed through a wet etching process. The etching chemical may include HF, for example.

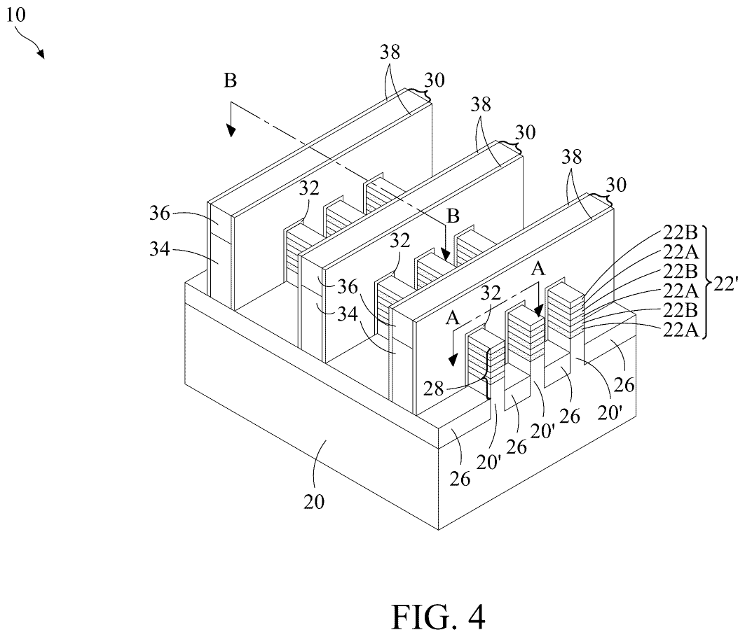

Referring to FIG. 4, dummy gate stacks 30 and gate spacers 38 are formed on the top surfaces and the sidewalls of (protruding) fins 28. The respective process is illustrated as process 208 in the process flow 200 shown in FIG. 22. Dummy gate stacks 30 may include dummy gate dielectrics 32 and dummy gate electrodes 34 over dummy gate dielectrics 32. Dummy gate dielectrics 32 may be formed by oxidizing the surface portions of protruding fins 28 to form oxide layers, or by depositing a dielectric layer such as a silicon oxide layer. Dummy gate electrodes 34 may be formed, for example, using polysilicon or amorphous silicon, and other materials such as amorphous carbon may also be used.

Each of dummy gate stacks 30 may also include one (or a plurality of) hard mask layer 36 over dummy gate electrode 34. Hard mask layers 36 may be formed of silicon nitride, silicon oxide, silicon carbo-nitride, silicon oxy-carbo nitride, or multilayers thereof. The formation of dummy gate stacks 30 includes forming a dummy gate dielectric layer, depositing a dummy gate electrode layer over the dummy gate dielectric layer, depositing one or more hard mask layers, and then patterning the formed layers through a pattering process(es).

Next, gate spacers 38 are formed on the sidewalls of dummy gate stacks 30. In accordance with some embodiments of the present disclosure, gate spacers 38 are formed of a dielectric material such as silicon nitride (SiN), silicon carbide (SiC), silicon oxide (SiO₂), silicon carbo-nitride (SiCN), silicon oxynitride (SiON), silicon oxy-carbo-nitride (SiOCN), or the like, and may have a single-layer structure or a multilayer structure including a plurality of dielectric layers. The formation process of gate spacers 38 may include depositing one or a plurality of dielectric layers, and then performing an anisotropic etching process(es) on the dielectric layer(s). The remaining portions of the dielectric layer(s) are gate spacers 38.

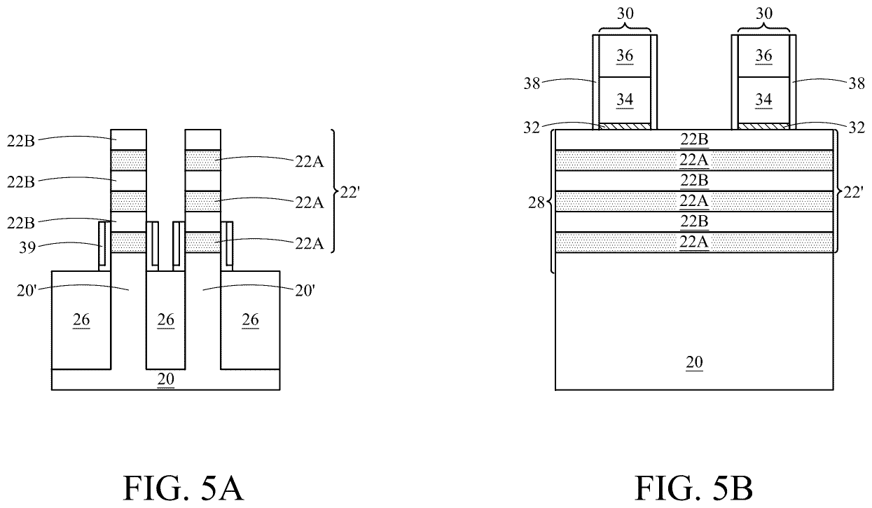

FIGS. 5A and 5B illustrate the cross-sectional views of the structure shown in FIG. 4. FIG. 5A illustrates the reference cross-section A-A in FIG. 4, which cross-section cuts through the portions of protruding fins 28 not covered by gate stacks 30 and gate spacers 38, and is perpendicular to the gate-length direction. Fin spacers 39, which are on the sidewalls of protruding fins 28, are also illustrated. FIG. 5B illustrates the reference cross-section B-B in FIG. 4, which reference cross-section is parallel to the lengthwise directions of protruding fins 28.

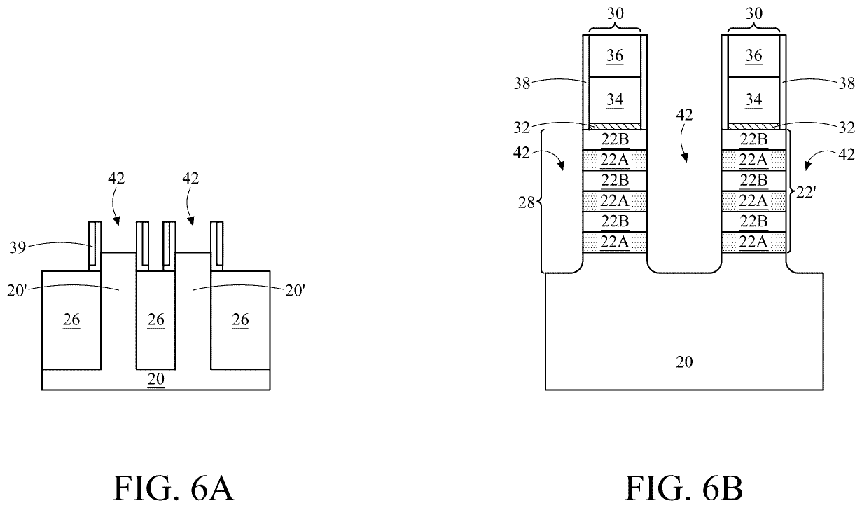

Referring to FIGS. 6A and 6B, the portions of protruding fins 28 that are not directly underlying dummy gate stacks 30 and gate spacers 38 are recessed through an etching process to form recesses 42. The respective process is illustrated as process 210 in the process flow 200 shown in FIG. 22. For example, a dry etch process may be performed using C₂F₆, CF₄, SO₂, the mixture of HBr, Cl₂, and O₂, the mixture of HBr, Cl₂, O₂, and CH₂F₂, or the like to etch multilayer semiconductor stacks 22′ and the underlying substrate strips 20′. The bottoms of recesses 42 are at least level with, or may be lower than (as shown in FIG. 6B), the bottoms of multilayer semiconductor stacks 22′. The etching may be anisotropic, so that the sidewalls of multilayer semiconductor stacks 22′ facing recesses 42 are vertical and straight.

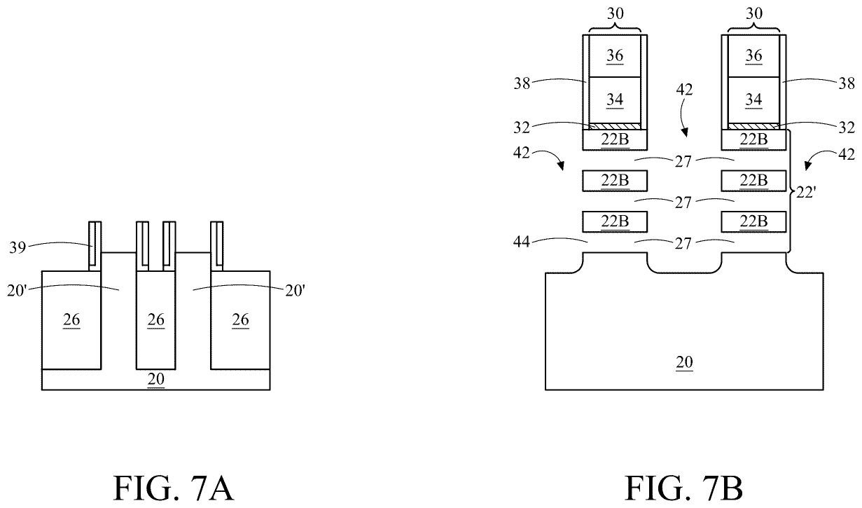

Next, referring to FIGS. 7A and 7B, the sacrificial layers 22A are removed through an etching process, so that spaces 27 are left between neighboring nanostructures 22B. The respective process is illustrated as process 212 in the process flow 200 shown in FIG. 22. The etching may be performed using an isotropic etching process, which may be a wet etching process or a dry etching process.

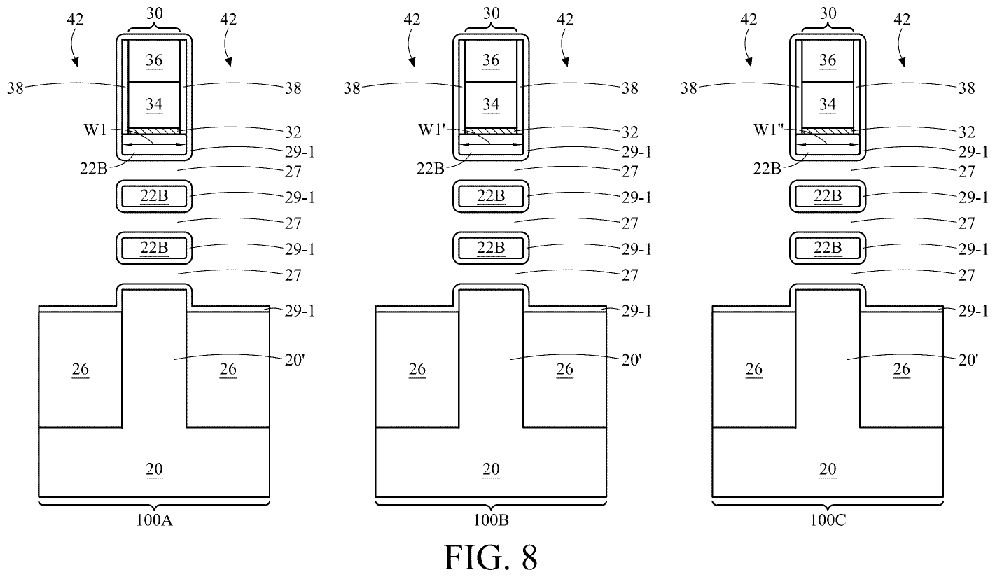

Referring to FIG. 8, a first dielectric layer (first sub layer) 29-1, which is used for forming disposable interposers, is deposited. The respective process is illustrated as process 214 in the process flow 200 shown in FIG. 22. In accordance with some embodiments, the wafer (and the device dies therein) includes two of three of device regions 100A, 100B, and 100C. The subsequently oxidation processes of the disposable interposers in device regions 100A, 100B, and 100C are performed differently using different process conditions and/or different chemicals/gases, as will be discussed in detail in subsequent paragraphs, so that the resulting disposable interposers may have different properties and different shapes. Each of the device regions 100A, 100B, and 100C may be used for forming a p-type transistor or an n-type transistor, and the conductivity type of the transistors in device regions 100A, 100B, and 100C can be the same or opposite.

The structures in device regions 100A, 100B, and 100C may be formed using common processes as shown in FIGS. 1 through FIGS. 7A and 7B. Accordingly, the materials and dimensions (such as the thicknesses of sacrificial layers 22A and nanostructures 22B) in one of device regions 100A, 100B, and 100C may be the same as in other ones of the device regions 100A, 100B, and 100C. In accordance with some embodiments, the width W1, W1′, and W1″ of nanostructures 22B may be the same as each other or different from each other.

In accordance with some embodiments, dielectric layer 29-1 is deposited as a conformal layer using a conformal deposition process. Dielectric layer 29-1 may be deposited into device regions 100A, 100B, and 100C simultaneously. The deposition method may include ALD such as thermal ALD or PEALD. The material of dielectric layer 29-1 may include an oxide such as silicon oxide, while other materials such as SiOC, SiON, Al₂O₃, or the like may be used. The process of depositing dielectric layer 29-1 is stopped before the portions of the dielectric layer 29-1 on neighboring nanostructures 22B merge with each other, with adequate spacing being left for the seam-free filling of a second dielectric layer.

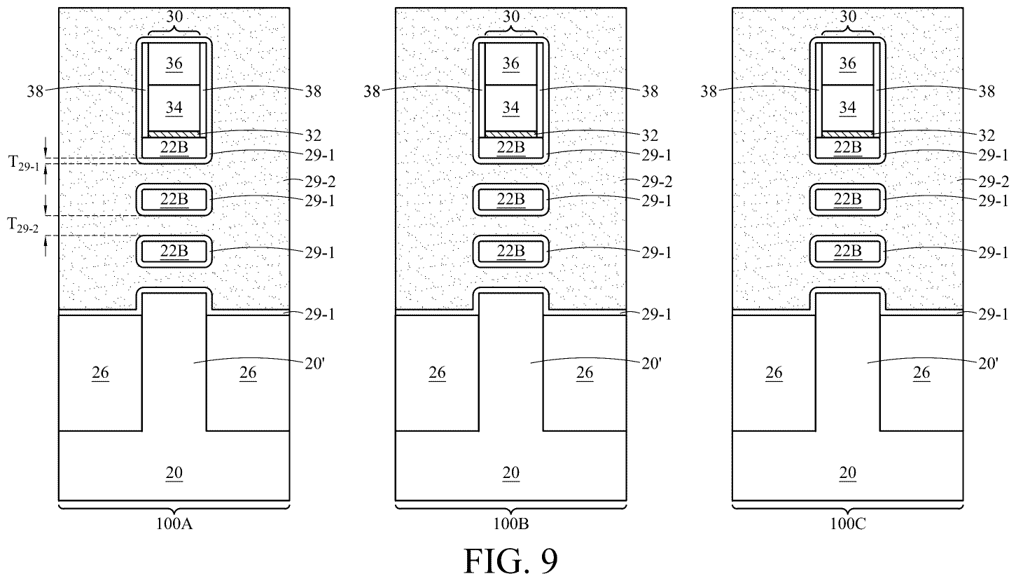

Dielectric layer 29-1, being conformal, may have the tendency of generating seams if dielectric layer 29-1 is deposited to fill all the spacings between neighboring nanostructures 22B. In accordance with some embodiments, as shown in FIG. 9, dielectric layer 29-2 (a second sub layer) is deposited through a bottom-up and seam-free process such as Flowable Chemical Vapor Deposition (FCVD). The respective process is illustrated as process 216 in the process flow 200 shown in FIG. 22.

In accordance with some embodiments in which FCVD is used, a silicon-and-nitrogen-containing precursor (for example, trisilylamine (TSA) or disilylamine (DSA)) is used, and the resulting dielectric layer 29-1 is flowable. In accordance with alternative embodiments, the dielectric layer 29-2 is formed using an alkylamino-silane-based precursor. During the deposition, plasma may be turned on to activate the gaseous precursors for forming the flowable oxide.

After the dielectric layer 29-2 is formed, dielectric layer 29-2 is cured into a solid. In accordance with some example embodiments, the curing process is performed using a Ultra-Violet (UV) light to treat the flowable dielectric layer 29-2. During the UV treatment, an oxygen-containing process gas may be conducted into the process chamber in which the wafer is placed. The oxygen-containing process gas may include oxygen (O₂), ozone (O₃), or the combinations thereof. In addition, carrier gases such as argon, helium, or the like may also be added along with the oxygen-containing process gas. The curing process may also be free from, or may include, a wet curing process, in which steam (H₂O) is used as the process gas.

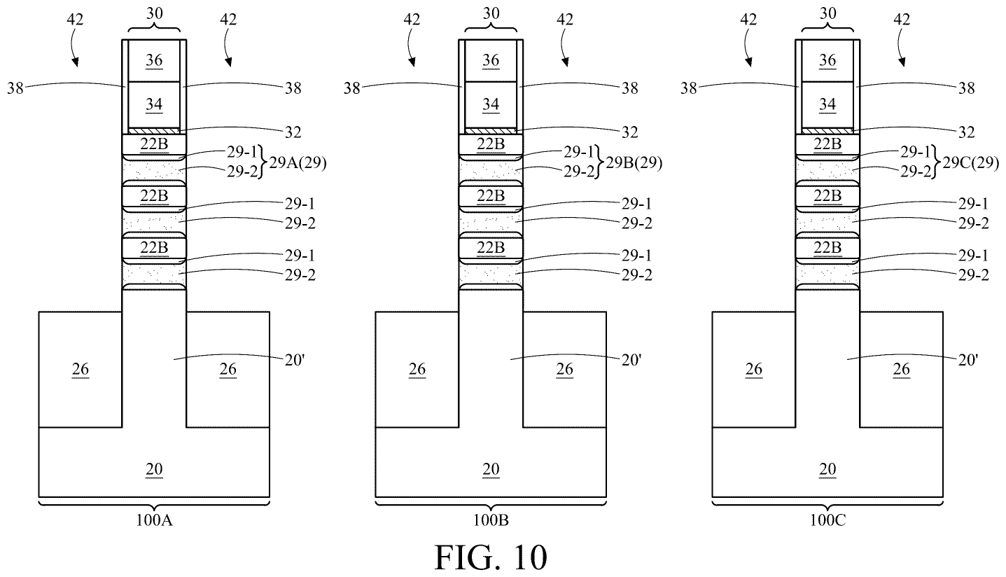

Referring to FIG. 10, dielectric layers 29-1 and 29-2 are etched in an etching process to form disposable interposers 29, which includes the disposable interposers 29A, 29B, and 29C in device regions 100A, 100B, and 100C, respectively. The respective process is illustrated as process 218 in the process flow 200 shown in FIG. 22. In the trimming process, the portions of dielectric layers 29-1 and 29-2 outside of spaces 27 (FIG. 8) are removed, while the portions in the spaces 27 are left, and are connectively referred to as disposable interposers 29, or disposable oxide interposers (DOIs) 29. The etching process may include an anisotropic etching process, followed by a light isotropic etching process.

The thicknesses of dielectric layers 29-1 and 29-2 affect the structure. For example, if dielectric layer 29-1 is too thick, there is no enough space for the seam-free dielectric layer 29-2 to adequately flow into the remaining spacing, and random seams may occur. On the other hand, if dielectric layer 29-2 is too thick, since dielectric layer 29-2 has a higher etching rate in subsequent formation of inner spacers, the throughout-wafer loading is high, and thus the dielectric layer 29-2 in different parts of the wafer have significantly different etching rates. In accordance with some embodiments, the thickness T₂₉₋₁ of dielectric layers 29-1 and the thickness T₂₉₋₂ of dielectric layer 29-2 are selected to balance the requirement of reducing seams and the requirement of having high through-wafer uniformity. For example, the thickness ratio T₂₉₋₁/T₂₉₋₂ may be in the range between about 1:1 and about 1:1.4.

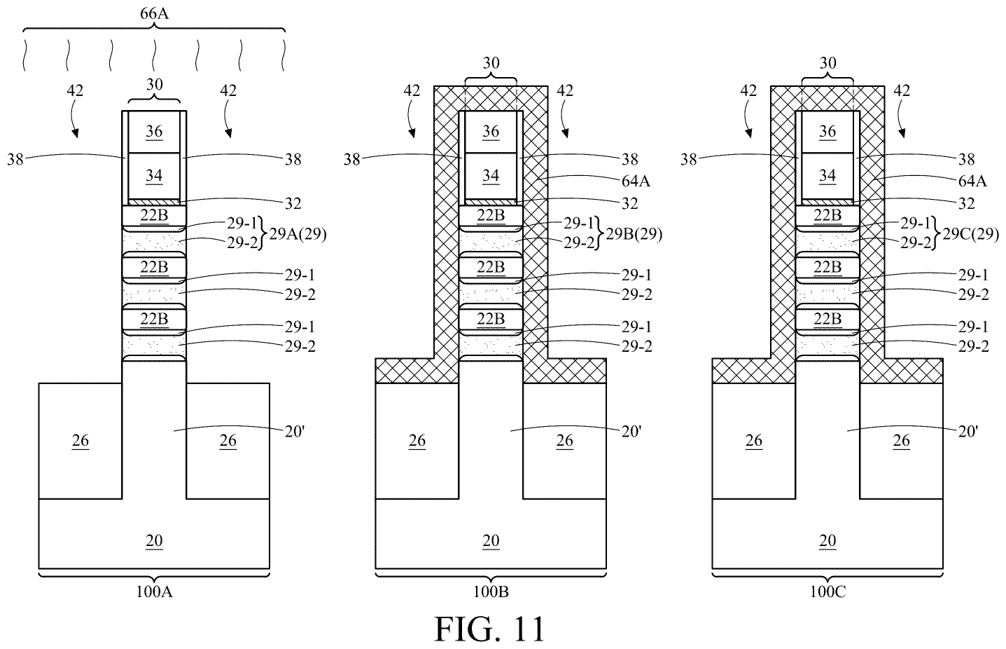

Dielectric layer 29-2, being formed using FCVD and thus having high number of NH bonds, may have lower quality (higher etching rate and/or lower density) than the dielectric layer 29-1 that has higher quality. Accordingly, an oxidation process is performed to convert the NH bonds in dielectric layer 29-2 into Si—O bonds. The converted (oxidized) dielectric layer 29-2 thus will have higher quality. The quality of the oxidized dielectric layer 29-2 is determined by the oxidation process. FIGS. 11, 12, and 13 illustrate the disposable interposers 29 in device regions 100A, 100B, and 100C are oxidized using different methods, which may be wet oxidation methods, and thus have different quality. The processes shown in FIGS. 11, 12, and 13 may be inversed to any order.

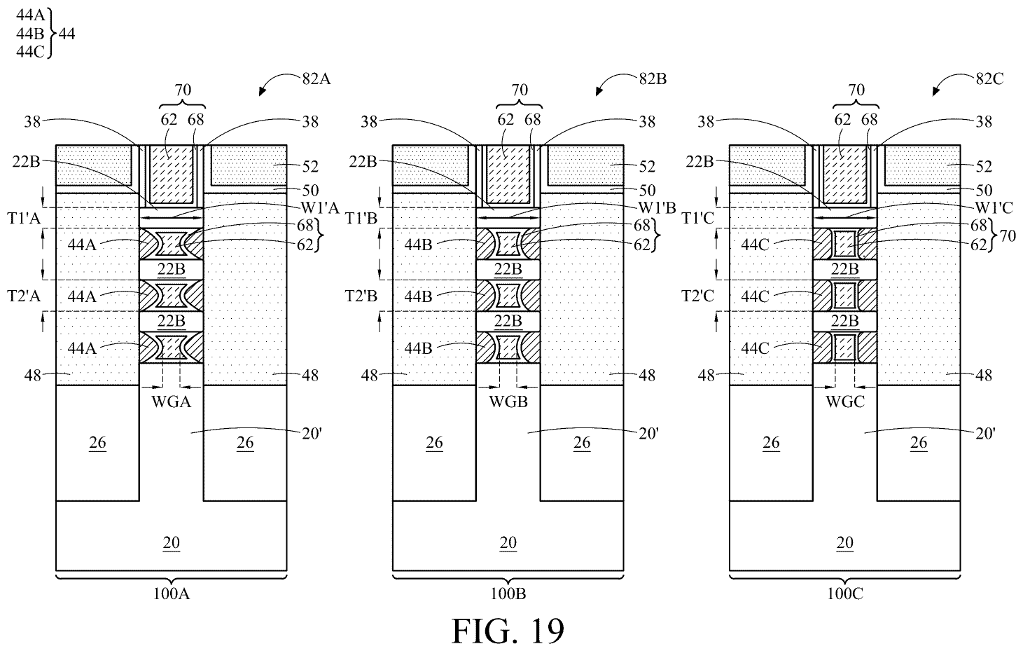

It is appreciated that the different oxidation processes in device regions 100A, 100B, and 100C result in the profiles of the resulting inner spacers and gate stacks to be different, and have different gate control ability and different source/drain-to-gate leakage. Some of the circuits may have higher requirement of gate control ability over reducing leakage, while some other circuits may have higher requirement of reducing leakage over gate control ability. Accordingly, the formation of a wafer (and device dies) may adopt any one, two, or all three of the oxidation processes as shown in FIGS. 11, 12, and 13, depending on circuit requirement. A wafer (and a device die) may also include one, two, or three of the structures as shown in FIG. 19 in any combination. In the embodiments in which more than one oxidation methods are used, hard masks may be used to achieve selected oxidation in selected device regions.

In accordance with alternative embodiments, no hard mask is formed for the subsequently discussed oxidation process, and all disposable interposers throughout the wafer are oxidized in the same process, which may be selected from the process as described referring to FIG. 11, 12, or 13.

Referring to FIG. 11, a patterned hard mask 64A (comprising BN, TiN, AlN, AIO, or the like) is formed to cover and protect the structures in device regions 100B and 100C, leaving the structure in device region 100A exposed. A first oxidation process is then performed on the disposable interposers 29A in device region 100A. The respective process is illustrated as process 220 in the process flow 200 shown in FIG. 22. Since dielectric layer 29-1 has little (if any) or no NH bonds, the quality of dielectric layer 29-1 may be high already. The oxidation process thus may have little or no effect on dielectric layers 29-1. The oxidation of interposers 29A and (subsequently 29B and 29C) is mainly (or essentially) oxidizing dielectric layer 29-2, and thus the subsequently oxidation process is also discussed as the oxidation of dielectric layer 29-2.

The first oxidation process 66A is performed using a first process condition and a first chemical, which may include spraying hot de-ionized water (DI water) on wafer 10 in accordance with some embodiments. The temperature of the DI water may be higher than room temperature (around 21° C.), and may be in the range between about 60° C. and about 80° C. After the first oxidation process, hard mask 64A is removed.

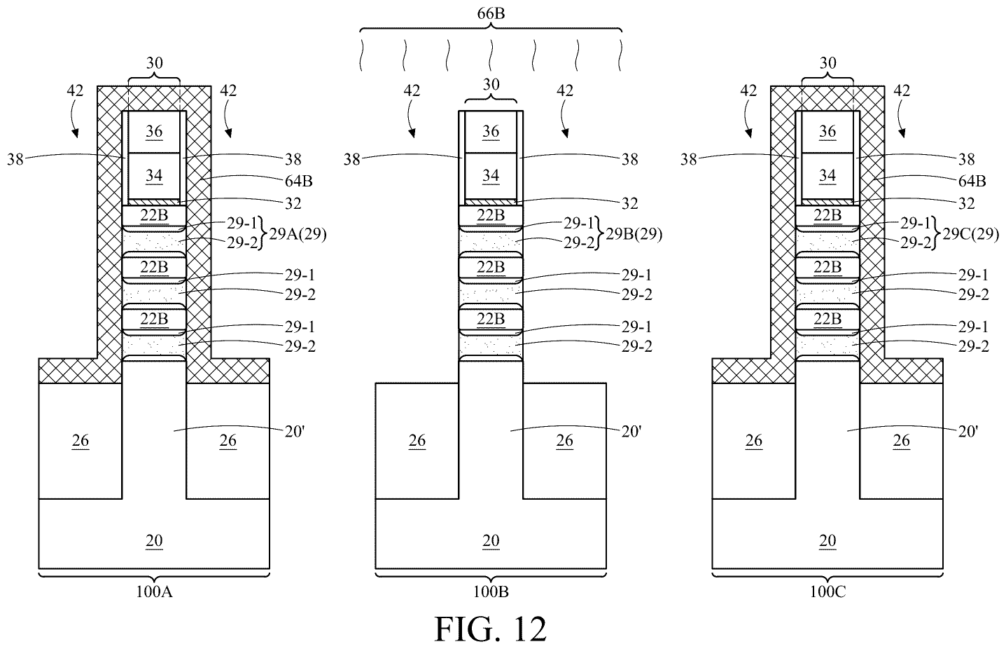

Referring to FIG. 12, a patterned hard mask 64B (comprising BN, TiN, AlN, AIO, or the like) is formed to cover and protect the structures in device regions 100A and 100C, leaving the structure in device region 100B exposed. A second wet oxidation process 66B is performed using a second process condition and/or a second chemical different from the first process condition and/or the first chemical. The respective process is illustrated as process 222 in the process flow 200 shown in FIG. 22. The second oxidation process 66B may result in a higher degree of oxidation (with a higher percentage of NH bonds being converted to Si—O bonds) of dielectric layers 29-2 than the first oxidation process.

In accordance with some embodiments, the second oxidation process 66B includes the spray of the wafer with a mixture of sulfuric acid (H₂SO₄) and hydrogen peroxide (H₂O₂), which are collectively referred to as a Sulfuric Peroxide Mixture (SPM). The volume ratio of (H₂SO₄): (H₂O₂) in the SPM may be in the range between about 1.5:1 and about 3:1. The temperature of the SPM may be in the range between about 85° C. and about 95° C.

The second oxidation process 66B may also include (After the spray of the SPM) the spray of a chemical solution (sometimes referred to as Standard Clean 1 (SC1) solution) on the wafer. The chemical solution comprises NH₄OH, H₂O₂, and H₂O. The temperature of the SC1 solution may be in the range between about 35° C. and about 45° C. After the second oxidation process 66B, hard mask 64B is removed.

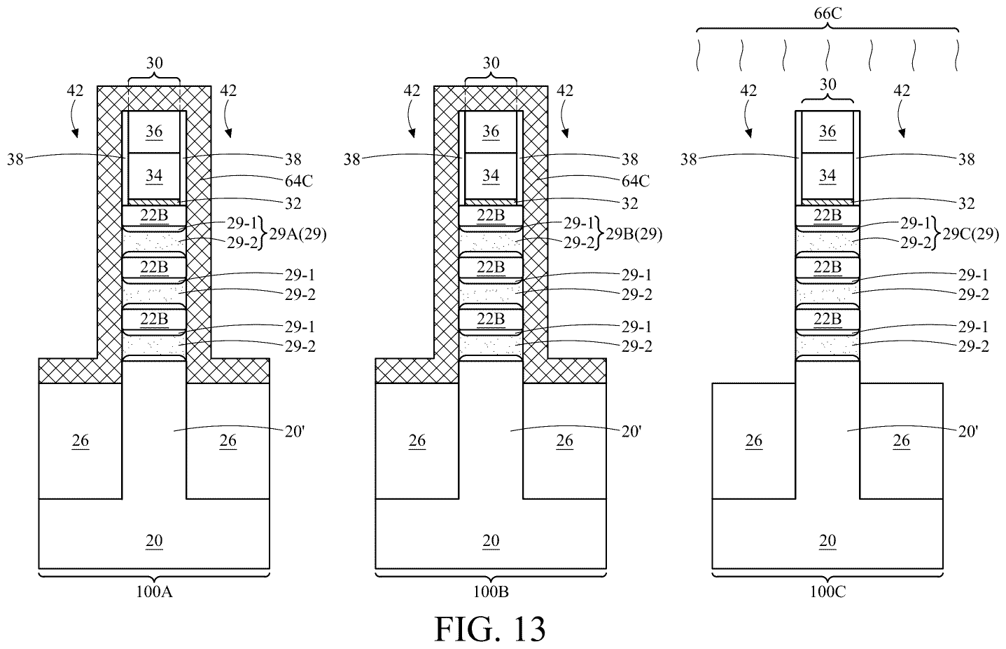

Next, referring to FIG. 13, a patterned hard mask 64C (comprising BN, TiN, AlN, AlO, or the like) is formed to cover and protect the structures in device regions 100A and 100B, leaving the structure in device region 100C exposed. A third wet oxidation process 66C is performed using a third process condition and/or a third chemical different from the first and the second process conditions and/or the first and second chemicals. The respective process is illustrated as process 224 in the process flow 200 shown in FIG. 22. The third oxidation process 66C may have a higher degree of oxidation (with more percentage of NH bonds being converted to Si—O bonds) than the second oxidation process 66B.

In accordance with some embodiments, the third oxidation process 66C includes the spray of hot SPM. The volume ratio of (H₂SO₄): (H₂O₂) in the SPM may be in the range between about 2:1 and about 9:1. The temperature of the chemical used in the third oxidation process 66C may be higher than the chemical used in the second oxidation process 66B, for example, by a temperature difference higher than about 5°, higher than about 10° C., or higher. For example, the temperature of the SPM may be in the range between about 95° C. and about 105° C.

The third oxidation process 66C may also include the spray of the SC1 solution following the spray of the SPM. The temperature of the SC1 solution be the same as or different from the temperature of the SC1 solution in the second oxidation process 66B. For example, in the third oxidation process 66C, the temperature of the SC1 solution may be in the range between about 35° C. and about 45° C.

In accordance with some embodiments, as aforementioned, the second oxidation process 66B and the third oxidation process 66C may be performed using the same chemical, except that the temperature of the chemical used in the third oxidation process 66C is higher than that of the second oxidation process 66B. After the third oxidation process 66C, hard mask 64C is removed.

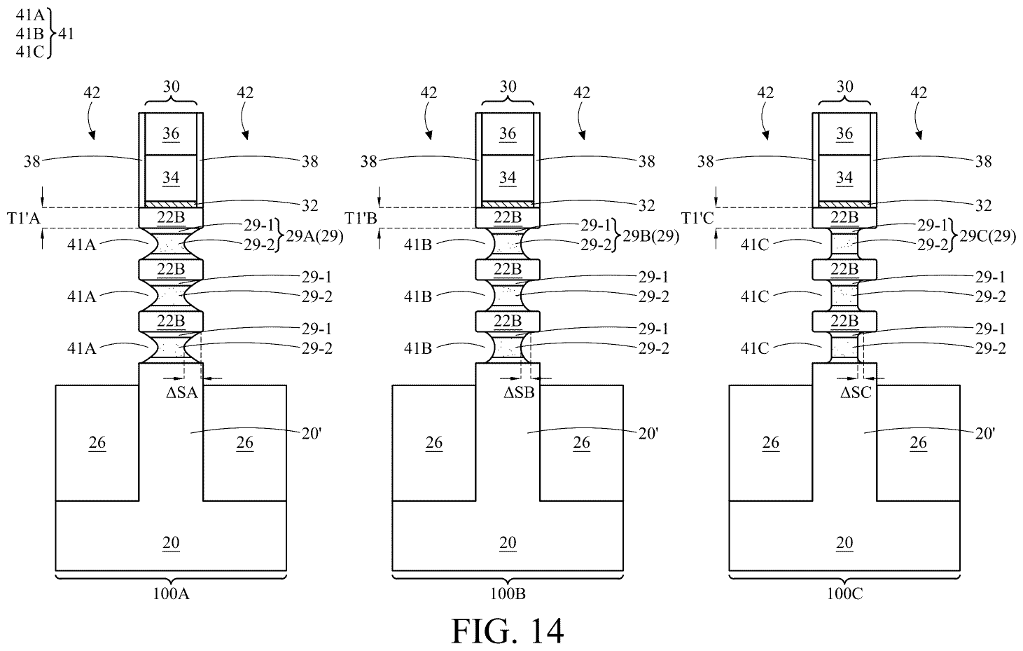

Next, referring to FIG. 14, disposable interposers 29A, 29B, and 29C are laterally recessed, and may be recessed in a same etching process. The respective process is illustrated as process 226 in the process flow 200 shown in FIG. 22. The recessing may be performed through a wet etching process or a dry etching process. The dry etching process may be performed using the mixture of NF₃ and NH₃ or the mixture of HF and NH₃. The wet etching process may be performed using a diluted HF solution. Lateral recesses 41 (including 41A, 41B, and 41C) are thus formed.

Due to the different oxidation processes as discussed, the second oxidation process 66B has a higher degree of oxidation than the first oxidation process 66A, and the third oxidation process 66C has a higher degree of oxidation than the second oxidation process 66B. The degree of oxidation may be reflected by the different etching rates of the disposable interposers 29A, 29B, and 29C. The dielectric layer 29-2 in device regions 100A, 100B, and 100C are referred to as 29-2 (100A), 29-2 (100B), and 29-2 (100C), respectively hereinafter. For example, if a same HF solution including 1 part of HF and 500 parts of de-ionized water is used to etch dielectric layers 29-2 (100A), 29-2 (100B), and 29-2 (100C), the etching rates of 29-2 (100A) may be in the range between about 60 Å and about 72 Å. The etching rates of 29-2 (100B) may be in the range between about 40 Å and about 48 Å. The etching rates of 29-2 (100C) may be in the range between about 17 Å and about 27 Å.

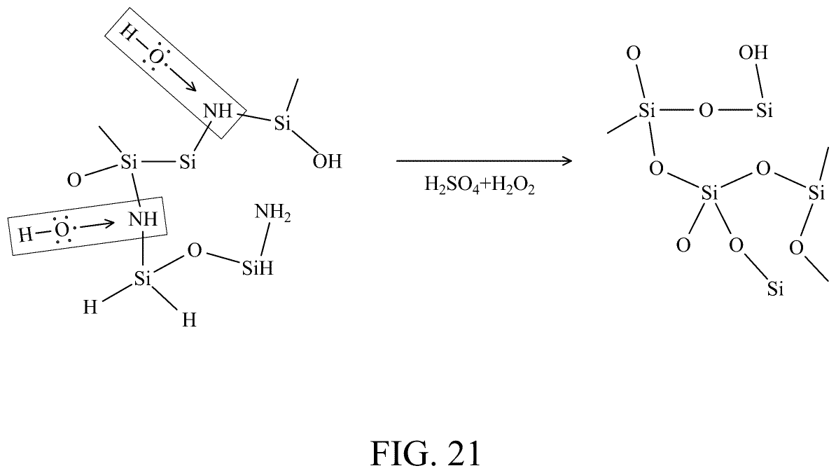

FIG. 21 schematically illustrates the structures of dielectric layer 29-2 before and after the oxidation using SPM. The structure change reflects the chemical reaction in the second oxidation process 66B (FIG. 12) and the third oxidation process 66C (FIG. 13). The structure change caused by the first oxidation process 66A (FIG. 11) is also similar to what is shown in FIG. 21, with a lower conversion rate.

As shown in FIG. 21, before the oxidation, multiple NH bonds are presented in the dielectric layer 29-2. After the oxidation, the NH bonds are converted into Si—O—Si bonds. The chemical equation of the reaction may be expressed as:

$${H}_{2} {SO}_{4} + {H}_{2} {O}_{2} \to {H}_{2} {SO}_{5} + {H}_{2} O \qquad [ Eq . 1 ]$$

H₂SO₅ is converted as H₂SO₄* radicals and OH* radicals. The number of the generated H₂SO₄* radicals and OH* radicals are related to the temperature of the oxidation chemical (including SPM), and the higher the temperature is, the more H₂SO₄* radicals and OH* radicals are generated. Accordingly, more H₂SO₄* radicals and OH* radicals in the third oxidation process 66C (FIG. 13) are generated than in the second oxidation process 66B (FIG. 12).

The H₂SO₄* radicals and OH* radicals result in the conversion of NH bonds to Si—O bonds, as shown in the following chemical equations:

$${OH}^{*} + Si - NH \to Si - OH + {NH}^{*} \qquad [ Eq . 2 ]$$

$${OH}^{*} + Si - OH \to Si - O + {H}_{2} O \qquad [ Eq . 3 ]$$

Accordingly, with more H₂SO₄* radicals and OH* radicals being generated, the conversion rate from NH bonds to Si—O bonds is higher. The third oxidation process 66C thus may generate silicon oxide with good quality, which quality is close to the quality of dielectric layer 29-1 formed using ALD.

Due to the lower quality and higher etching rate of the dielectric layer 29-2 in the disposable interposer 29A (in device region 100A), the resulting lateral recesses 41A have V-shapes. With recesses 41A having V-shapes, the edges of disposable interposers 29A may have two straight (but slanted) edges facing the V-shaped recesses 41A. The corner portions of the upper and bottom surfaces of nanostructures 22B facing the U-shaped recesses 41B may also be recessed slightly to form parts of the V-shape.

Due to the relatively moderate quality and moderate etching rate of the dielectric layer 29-2 in the disposable interposer 29B (in device region 100B), the resulting lateral recesses 41B have U-shapes. With recesses 41B having U-shapes, the upper and bottom surfaces of nanostructures 22B facing the U-shaped recesses 41B are straight and horizontal, and are connected to continuously curved edges of dielectric layers 29-1 and 29-2.

Due to the higher quality and lower etching rate of the dielectric layer 29-2 in the disposable interposer 29C (in device region 100C), the resulting lateral recesses 41C have square-shapes. With recesses 41C having square-shapes, the upper and bottom surfaces of nanostructures 22B facing the square-shaped recesses 41C are straight and horizontal, and are connected to continuously curved edges of dielectric layers 29-1. The edges of dielectric layers 29-2 are vertical and straight, and are also connected to the continuously curved edges of dielectric layers 29-1. The upper and bottom surfaces of nanostructures 22B facing the U-shaped recesses 41B are straight and horizontal, and are connected to continuously curved edges of dielectric layers 29-1.

It is appreciated that due to the rounded profiles of recesses 41A, 41B, and 41C (collectively referred to as recesses 41), it may be difficult to determine whether the shapes of some of recesses are V-shaped, U-shaped, or square-shapes. The shape difference between recesses 41A, 41B, and 41C, however, can be determined through comparison. In FIG. 14, the lateral recessing distance ΔSA is defined as the lateral distance between the outmost tip and the innermost tip of disposable interposers 29A. The lateral recessing distance ASB is defined as the lateral distance between the outmost tip and the innermost tip of disposable interposers 29B. The lateral recessing distance ΔSC is defined as the lateral distance between the outmost tip and the innermost tip of disposable interposers 29C. In accordance with some embodiments, there exists the relationship ΔSC>ΔSB>ΔSA. Furthermore, the ratios have the relationship ΔSC/T1′A>ΔSB/T1′B>ΔSA/T1′C.

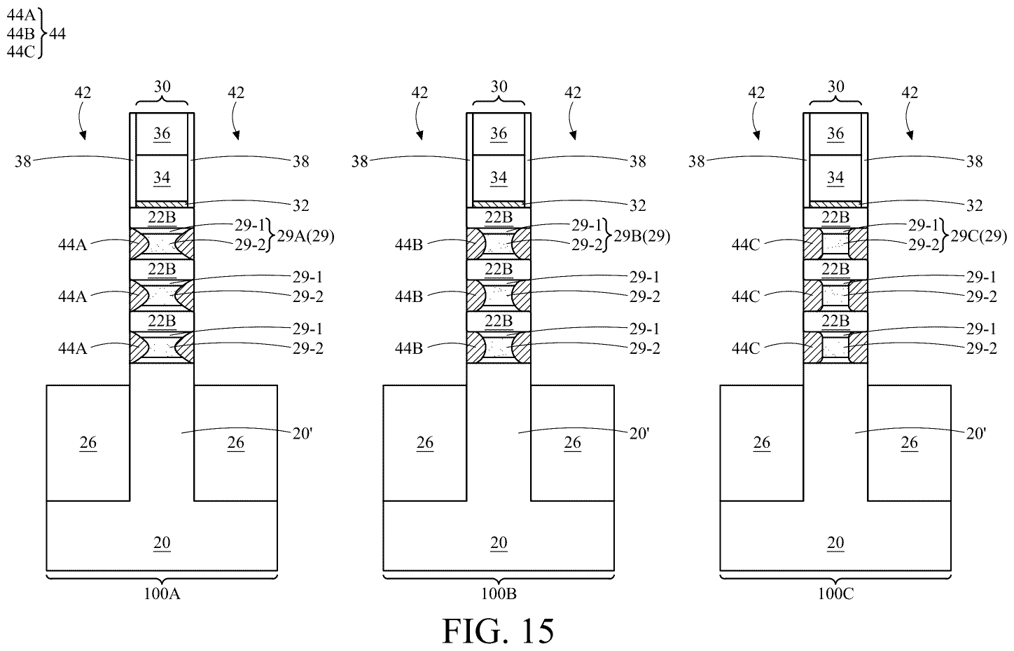

Referring to FIG. 15, lateral recesses 41A, 41B, and 41C are filled to form inner spacers 44 (including 44A, 44B, and 44C). The respective process is illustrated as process 228 in the process flow 200 shown in FIG. 22. In accordance with some embodiments, the formation of inner spacers 44 includes depositing a conformal dielectric layer, which extends into the lateral recesses 41. Next, an etching process (also referred to as a spacer trimming process) is performed to trim the portions of the spacer layer outside of the lateral recesses 41, leaving the portions of the spacer layer in the lateral recesses 41. The remaining portions of the spacer layer are referred to as inner spacers 44. Inner spacers 44 may be formed of or comprise silicon nitride, silicon oxynitride, silicon carbonitride, or the like.

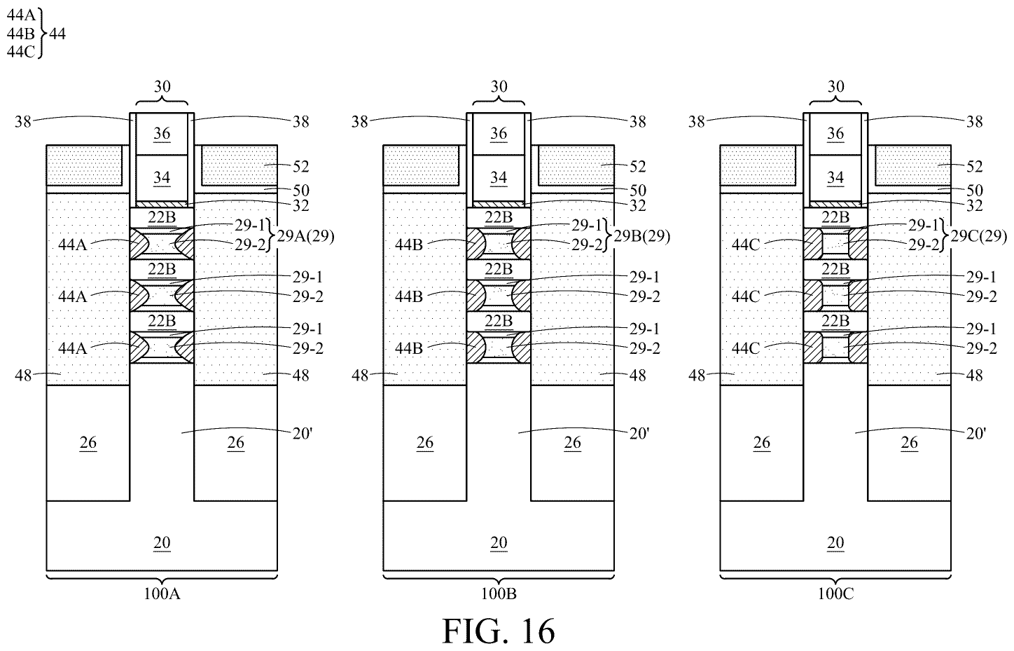

Referring to FIG. 16, epitaxial source/drain regions 48 are formed in recesses 42 through selective epitaxy. The respective process is illustrated as process 230 in the process flow 200 shown in FIG. 22. Depending on whether the resulting transistor is a p-type transistor or an n-type transistor, a p-type or an n-type impurity may be in-situ doped with the proceeding of the epitaxy. For example, when the resulting transistor is a p-type transistor, silicon germanium boron (SiGeB), silicon boron (SiB), or the like may be grown. Conversely, when the resulting transistor is an n-type transistor, silicon phosphorous (SiP), silicon carbon phosphorous (SiCP), or the like may be grown.

FIG. 16 further illustrates the cross-sectional view of the structure after the formation of Contact Etch Stop Layer (CESL) 50 and Inter-Layer Dielectric (ILD) 52. The respective process is illustrated as process 232 in the process flow 200 shown in FIG. 22. CESL 50 may be formed of silicon oxide, silicon nitride, silicon carbo-nitride, or the like, and may be formed using CVD, ALD, or the like. ILD 52 may include a dielectric material formed using, for example, FCVD, spin-on coating, CVD, or any other suitable deposition method. ILD 52 may be formed of an oxygen-containing dielectric material, which may include silicon oxide, Phospho-Silicate Glass (PSG), Boro-Silicate Glass (BSG), Boron-Doped Phospho-Silicate Glass (BPSG), Undoped Silicate Glass (USG), or the like.

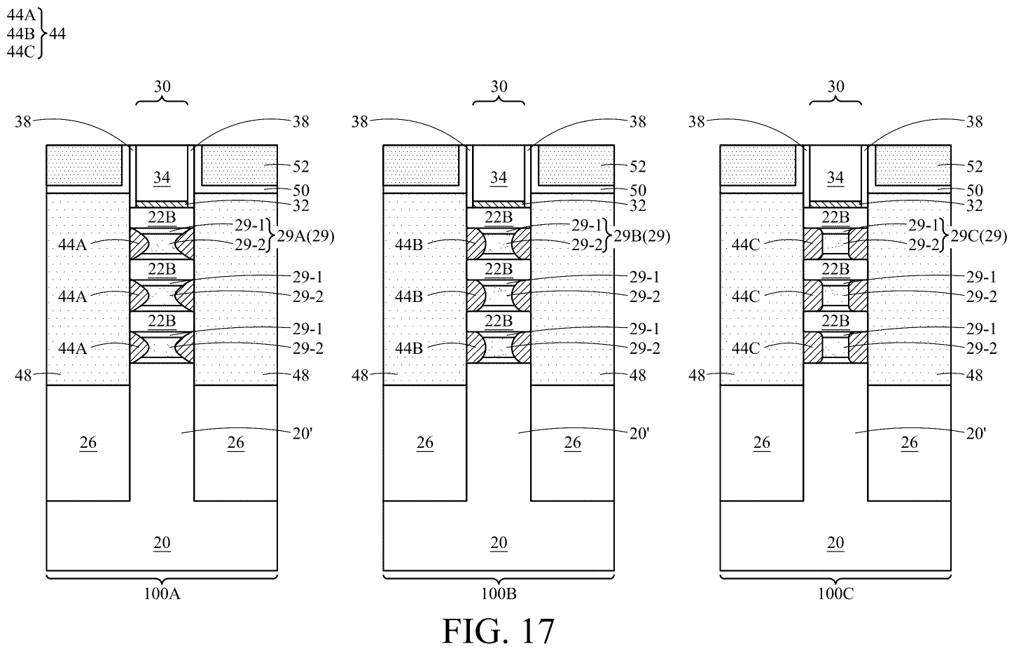

Referring to FIG. 17, CESL 50 and ILD 52 are planarized through a planarization process such as a CMP process or a mechanical grinding process. The respective process is illustrated as process 234 in the process flow 200 shown in FIG. 22. In accordance with some embodiments, the planarization process may remove hard masks 36 to reveal dummy gate electrodes 34, as shown in FIG. 17. In accordance with alternative embodiments, the planarization process may reveal, and is stopped on, hard masks 36. In accordance with some embodiments, after the planarization process, the top surfaces of dummy gate electrodes 34 (or hard masks 36), gate spacers 38, and ILD 52 are level within process variations.

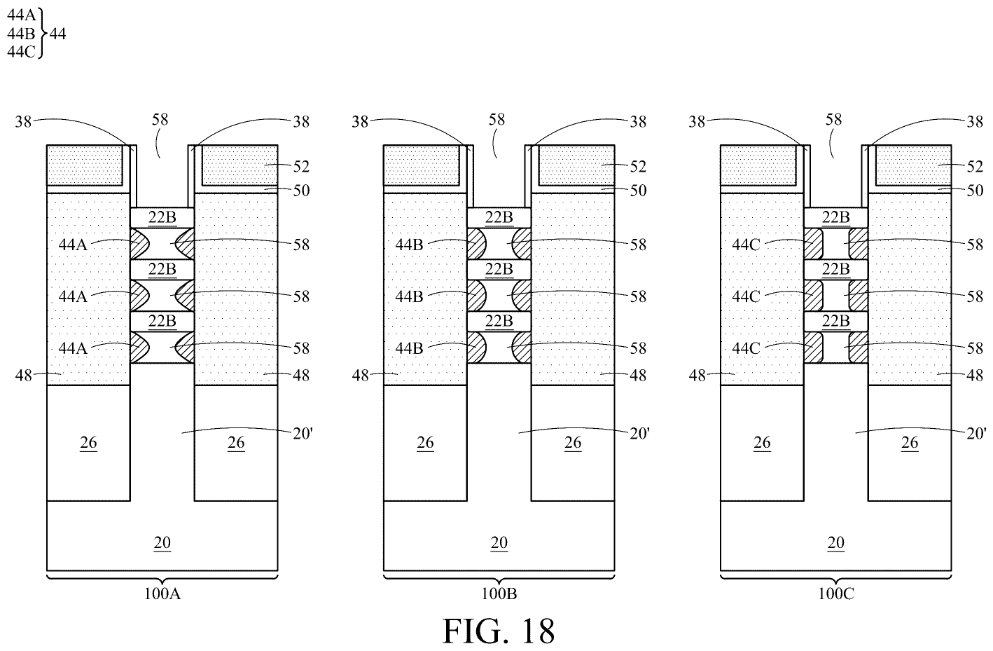

Next, dummy gate electrodes 34 and dummy gate dielectrics 32 (and hard masks 36, if remaining) are removed in one or more etching processes, so that recesses 58 are formed, as shown in FIG. 18. The respective process is illustrated as process 236 in the process flow 200 shown in FIG. 22. In accordance with some embodiments, dummy gate electrodes 34 and dummy gate dielectrics 32 are removed through an anisotropic and/or isotropic dry etch process(es). For example, the etching process may be performed using reaction gas(es) that selectively etch dummy gate electrodes 34 and dummy gate dielectrics 32 at faster rates than ILD 52. Each recess 58 exposes and/or overlies portions of multilayer stacks 22′, which include the future channel regions in subsequently completed transistors.

Disposable interposers 29 are then removed to extend recesses 58 between nanostructures 22B. The respective process is illustrated as process 238 in the process flow 200 shown in FIG. 22. Disposable interposers 29 may be removed by performing an isotropic etching process such as dry etching process or a wet etching process using an etchant that is selective to the materials of disposable interposers 29, while nanostructures 22B and substrate 20 remain relatively un-etched as compared to disposable interposers 29.

In accordance with some embodiments in which disposable interposers 29 are formed of silicon oxide (DOI), when dry etching is performed, the etching gases may include the mixture of NF₃ and NH₃, the mixture of HF and NH₃, or the like. When wet etching is performed, diluted HF may be used.

Referring to FIG. 19, replacement gate stacks 70 including gate dielectrics 62 and gate electrodes 68 are formed. The respective process is illustrated as process 240 in the process flow 200 shown in FIG. 22. In accordance with some embodiments, each of gate dielectrics 62 includes an interfacial layer and a high-k dielectric layer over the interfacial layer. The interfacial layer may be formed of or comprises silicon oxide, which may be deposited through a conformal deposition process such as ALD or CVD, or through an oxidation process. In accordance with some embodiments, the high-k dielectric layers comprise one or more dielectric layers. For example, the high-k dielectric layer(s) may include a metal oxide or a silicate of hafnium, aluminum, zirconium, lanthanum, manganese, barium, titanium, lead, and combinations thereof.

Gate electrodes 68 may include a metal-containing material such as TiN, TaN, TiAl, TiAIC, cobalt, ruthenium, aluminum, tungsten, combinations thereof, and/or multilayers thereof. For example, gate electrodes 68 may comprise any number of layers, any number of work function layers, and possibly a filling metal. Gate dielectrics 62 and gate electrodes 68 also fill the spaces between adjacent ones of nanostructures 22B, and fill the spaces between the bottom ones of nanostructures 22B and the underlying substrate strips 20′. After the filling of recesses 58, a planarization process such as a CMP process or a mechanical grinding process is performed to remove the excess portions of the gate dielectrics and the material of gate electrodes 68, which excess portions are over the top surface of ILD 52. Gate electrodes 68 and gate dielectrics 62 are collectively referred to as gate stacks 70. Transistor 82A, 82B, and 82C are thus formed in device regions 100A, 100B, and 100C, respectively.

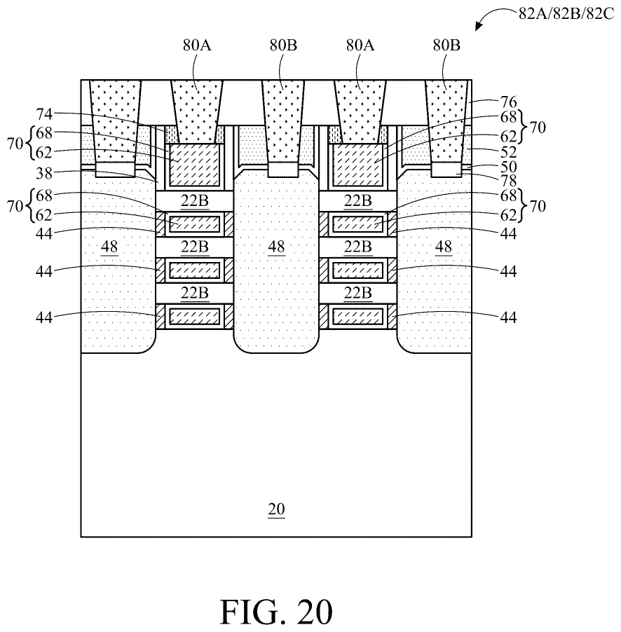

FIG. 20 illustrates the formation of overlying features. The structure shown in FIG. 20 may reflect the continued formation of the structure in any of device regions 100A, 100B, and 100C, and the details of the structure in device regions 100A, 100B, and 100C may be found from FIG. 19.

In a subsequent process, as shown in FIG. 20, gate stacks 70 are recessed, so that recesses are formed directly over gate stacks 70 and between opposing portions of gate spacers 38. A gate mask 74 comprising one or more layers of dielectric material, such as silicon nitride, silicon oxynitride, or the like, is filled in each of the recesses, followed by a planarization process to remove excess portions of the dielectric material extending over ILD 52.

ILD 76 is deposited over ILD 52. An etch stop layer (not shown) may be (or may not be) deposited before the formation of ILD 76. In accordance with some embodiments, ILD 76 is formed through FCVD, CVD, PECVD, or the like. ILD 76 is formed of a dielectric material, which may be selected from silicon oxide, PSG, BSG, BPSG, USG, or the like.

ILD 76, ILD 52, CESL 50, and gate masks 74 are then etched to form recesses (occupied by contact plugs 80A and 80B) exposing surfaces of source/drain regions 48 and/or gate stacks 70. The recesses may be formed through etching using an anisotropic etching process, such as RIE, NBE, or the like. Although FIG. 20 illustrates that contact plugs 80A and 80B are in a same cross-section, in various embodiments, contact plugs 80A and 80B may be formed in different cross-sections, thereby reducing the risk of shorting with each other.

Silicide regions 78 are formed over source/drain regions 48. Contact plugs 80B are formed over silicide regions 78. Also, contacts 80A (may also be referred to as gate contact plugs) are formed over and contacting gate electrodes 68. Transistor 82 is thus formed. The illustrated transistor 82 may be any of the transistor 82A, 82B, and 82C as shown in FIG. 19.

Referring back to FIG. 19, inner spacers 44A, 44B, and 44C include V-shaped inner sidewalls, U-shaped inner sidewalls, and square-shaped sidewalls. The details of the shapes are essentially the same as discussed referring to FIG. 14, and are not repeated herein. Due to the increasingly higher degree of oxidation in the oxidation processes 66A (FIG. 11), 66B (FIGS. 12), and 66C (FIG. 13), nanostructures 22B in device regions 100A, 100B, and 100C are oxidized with increasingly higher degrees. Accordingly, there exists relationship W1′A>W1′B>W1′C due to the lateral oxidation of nanostructures 22B. Also, the thicknesses of nanostructures 22B have the relationship T1′A>T1′B>T1′C. The heights of the inner spacers 44 and gate stack portions between nanostructures 22B has the relationship T2′A<T2′B<T2′C. The widths of gate stack portions between nanostructures 22B have the relationship WGA=WGB=WGC.

As shown in FIG. 19, the gate stack 70 in transistor 82A extends laterally closer to the edges of the respective overlying or underlying nanostructures 22B. The gate control is thus improved. On the other hand, some portions of inner spacers 44A may be too thin, and the leakage between source/drain region 48 and gate stack 70 in transistor 82A may be increased. Conversely, the gate stack 70 of transistor 82C extends laterally farther from the edges of respective overlying or underlying nanostructures 22B. The gate control of transistor 82C is thus inferior than the gate control of transistor 82A. On the other hand, the inner spacers 44C of transistor 82C have square shapes, and the leakage between source/drain region 48 and gate stack 70 may be reduced. Transistor 100B has balanced performance regarding gate control and leakage compared to transistors 82A and 82C.

The embodiments of the present disclosure have some advantageous features. By performing a wet oxidation process on the disposable interposers, the quality of the interposers may be improved. By adjusting the oxidation process conditions, the resulting disposable interposers and inner spacers may have different profiles. The replacement gate stacks may also have different profiles. Depending on the requirement of circuits, better gate control and/or lower leakage may be achieved.

In accordance with some embodiments of the present disclosure, a method comprises forming a first multilayer stack over a first semiconductor region, wherein the first multilayer stack comprises a first plurality of sacrificial layers and a first plurality of semiconductor nanostructures located alternatingly; removing the first plurality of sacrificial layers; forming a first plurality of disposable interposers between the first plurality of semiconductor nanostructures; performing a first oxidation process on the first plurality of disposable interposers; laterally recessing the first plurality of disposable interposers to form lateral recesses between the first plurality of semiconductor nanostructures; forming inner spacers in the lateral recesses; removing the first plurality of disposable interposers; and forming a replacement gate in spaces between the first plurality of semiconductor nanostructures.

In an embodiment, the forming the first plurality of disposable interposers comprises: a first deposition process to deposit a first dielectric layer; and a second deposition process to deposit a second dielectric layer on the first dielectric layer. In an embodiment, the first deposition process comprises a conformal deposition process, and the second deposition process comprises a bottom-up deposition process. In an embodiment, the first oxidation process is performed using de-ionized water. In an embodiment, the first oxidation process is performed using a chemical solution comprising sulfuric peroxide mixture.

In an embodiment, the method further comprises forming a second multilayer stack over a second semiconductor region, wherein the second multilayer stack comprises a second plurality of sacrificial layers and a second plurality of semiconductor nanostructures located alternatingly; forming a second plurality of disposable interposers to replace the second plurality of sacrificial layers; and performing a second oxidation process on the second plurality of disposable interposers, wherein the first oxidation process is a separate oxidation process than the second oxidation process.

In an embodiment, the first oxidation process is performed using a first process condition different from a second process condition of the second oxidation process. In an embodiment, the method further comprises forming a first mask to cover the second plurality of disposable interposers when the first oxidation process is performed; and forming a second mask to cover the first plurality of disposable interposers when the second oxidation process is performed.

In an embodiment, the first oxidation process and the second oxidation process are performed using chemical solutions comprising sulfuric peroxide mixture, and wherein the first oxidation process and the second oxidation process are performed at different temperatures. In an embodiment, the inner spacers have a V-shape in a cross-sectional view of the inner spacers. In an embodiment, the inner spacers have a U-shape in a cross-sectional view of the inner spacers. In an embodiment, the inner spacers have a rectangular shape in a cross-sectional view of the inner spacers.

In accordance with some embodiments of the present disclosure, a method comprises forming a first plurality of semiconductor nanostructures, with upper ones of the first plurality of semiconductor nanostructures overlapping lower ones of the first plurality of semiconductor nanostructures; forming a first disposable interposer between the first plurality of semiconductor nanostructures; performing a first oxidation process on the first disposable interposer; forming a second plurality of semiconductor nanostructures, with upper ones of the second plurality of semiconductor nanostructures overlapping lower ones of the second plurality of semiconductor nanostructures; forming a second disposable interposer between the second plurality of semiconductor nanostructures; and performing a second oxidation process on the second disposable interposer.

In an embodiment, the first oxidation process and the second oxidation process are separate oxidation processes. In an embodiment, the method further comprises forming a hard mask to cover the second plurality of semiconductor nanostructures, wherein the first oxidation process is performed when the hard mask is on the second plurality of semiconductor nanostructures; and removing the hard mask after the first oxidation process. In an embodiment, the first oxidation process and the second oxidation process are performed using different chemicals. In an embodiment, the method further comprises laterally recessing the first disposable interposer and the second disposable interposer simultaneously to form lateral recesses; and forming inner spacers in the lateral recesses.

In accordance with some embodiments of the present disclosure, a method comprises forming a first semiconductor nanostructure and a second semiconductor nanostructure overlapping and spaced apart from the first semiconductor nanostructure; depositing a first dielectric layer partially filling a space between the first semiconductor nanostructure and the second semiconductor nanostructure; depositing a second dielectric layer filling a remaining portion of the space; etching the first dielectric layer and the second dielectric layer to form a disposable interposer between the first semiconductor nanostructure and the second semiconductor nanostructure; performing an oxidation process on the disposable interposer; and etching the disposable interposer.

In an embodiment, the oxidation process is performed through wet oxidation at a temperature higher than room temperature. In an embodiment, the first dielectric layer is deposited through atomic layer deposition, and the second dielectric layer is deposited through flowable chemical vapor deposition.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first multilayer stack over a first semiconductor region, wherein the first multilayer stack comprises a first plurality of sacrificial layers and a first plurality of semiconductor nanostructures located alternatingly;
removing the first plurality of sacrificial layers;
forming a first plurality of disposable interposers between the first plurality of semiconductor nanostructures;
performing a first oxidation process on the first plurality of disposable interposers;
laterally recessing the first plurality of disposable interposers to form lateral recesses between the first plurality of semiconductor nanostructures;
forming inner spacers in the lateral recesses;
removing the first plurality of disposable interposers; and
forming a replacement gate in spaces between the first plurality of semiconductor nanostructures.

2. The method of claim 1, wherein the forming the first plurality of disposable interposers comprises:
a first deposition process to deposit a first dielectric layer; and
a second deposition process to deposit a second dielectric layer on the first dielectric layer.

3. The method of claim 2, wherein the first deposition process comprises a conformal deposition process, and the second deposition process comprises a bottom-up deposition process.

4. The method of claim 1, wherein the first oxidation process is performed using de-ionized water.

5. The method of claim 1, wherein the first oxidation process is performed using a chemical solution comprising sulfuric peroxide mixture.

6. The method of claim 1 further comprising:
forming a second multilayer stack over a second semiconductor region, wherein the second multilayer stack comprises a second plurality of sacrificial layers and a second plurality of semiconductor nanostructures located alternatingly;
forming a second plurality of disposable interposers to replace the second plurality of sacrificial layers; and
performing a second oxidation process on the second plurality of disposable interposers, wherein the first oxidation process is a separate oxidation process than the second oxidation process.

7. The method of claim 6, wherein the first oxidation process is performed using a first process condition different from a second process condition of the second oxidation process.

8. The method of claim 6 further comprising:
forming a first mask to cover the second plurality of disposable interposers when the first oxidation process is performed; and
forming a second mask to cover the first plurality of disposable interposers when the second oxidation process is performed.

9. The method of claim 6, wherein the first oxidation process and the second oxidation process are performed using chemical solutions comprising sulfuric peroxide mixture, and wherein the first oxidation process and the second oxidation process are performed at different temperatures.

10. The method of claim 1, wherein the inner spacers have a V-shape in a cross-sectional view of the inner spacers.

11. The method of claim 1, wherein the inner spacers have a U-shape in a cross-sectional view of the inner spacers.

12. The method of claim 1, wherein the inner spacers have a rectangular shape in a cross-sectional view of the inner spacers.

13. A method comprising:
forming a first plurality of semiconductor nanostructures, with upper ones of the first plurality of semiconductor nanostructures overlapping lower ones of the first plurality of semiconductor nanostructures;
forming a first disposable interposer between the first plurality of semiconductor nanostructures;
performing a first oxidation process on the first disposable interposer;
forming a second plurality of semiconductor nanostructures, with upper ones of the second plurality of semiconductor nanostructures overlapping lower ones of the second plurality of semiconductor nanostructures;
forming a second disposable interposer between the second plurality of semiconductor nanostructures; and
performing a second oxidation process on the second disposable interposer.

14. The method of claim 13, wherein the first oxidation process and the second oxidation process are separate oxidation processes.

15. The method of claim 13 further comprising:
forming a hard mask to cover the second plurality of semiconductor nanostructures, wherein the first oxidation process is performed when the hard mask is on the second plurality of semiconductor nanostructures; and
removing the hard mask after the first oxidation process.

16. The method of claim 13, wherein the first oxidation process and the second oxidation process are performed using different chemicals.

17. The method of claim 13 further comprising:
laterally recessing the first disposable interposer and the second disposable interposer simultaneously to form lateral recesses; and
forming inner spacers in the lateral recesses.

18. A method comprising:
forming a first semiconductor nanostructure and a second semiconductor nanostructure overlapping and spaced apart from the first semiconductor nanostructure;
depositing a first dielectric layer partially filling a space between the first semiconductor nanostructure and the second semiconductor nanostructure;
depositing a second dielectric layer filling a remaining portion of the space;
etching the first dielectric layer and the second dielectric layer to form a disposable interposer between the first semiconductor nanostructure and the second semiconductor nanostructure;
performing an oxidation process on the disposable interposer; and
etching the disposable interposer.

19. The method of claim 18, wherein the oxidation process is performed through wet oxidation at a temperature higher than room temperature.

20. The method of claim 18, wherein the first dielectric layer is deposited through atomic layer deposition, and the second dielectric layer is deposited through flowable chemical vapor deposition.
